(19) United States
(12) Patent Application Publication
(10) Pub. No.: US 2026/0020405 A1
(43) Pub. Date: Jan. 15, 2026

(54) MICRO LIGHT-EMITTING DIODE SUBSTRATE AND MANUFACTURING METHOD THEREOF

(71) Applicants: Hefei BOE Ruisheng Technology Co., Ltd., Hefei (Anhui) (CN); BOE TECHNOLOGY GROUP CO.,LTD., Beijing (CN)

(72) Inventors: Haifeng HU, Beijing (CN); Ting ZENG, Beijing (CN); Xin ZHA, Beijing (CN)

(73) Assignees: Hefei BOE Ruisheng Technology Co., Ltd., Hefei (Anhui) (CN); BOE TECHNOLOGY GROUP CO.,LTD., Beijing (CN)

(21) Appl. No.: 18/995,386

(22) PCT Filed: May 31, 2024
(86) PCT No.: PCT/CN2024/096624

§ 371 Date: Jan. 16, 2025

(30) Foreign Application Priority Data
Jun. 30, 2023 (CN) 202310807146.6

(51) Int. Cl. H10H 29/39; H10H 29/01; H10H 29/49

(52) U.S. Cl. CPC H10H 29/39; H10H 29/012; H10H 29/49

(57) ABSTRACT

A micro light emitting diode substrate and a manufacturing method thereof. The micro light-emitting diode substrate includes a substrate, a driver circuit layer, a plurality of micro light-emitting diodes, a plurality of connection via holes, and a plurality of conductive structures. The driver circuit layer is located on a first side of the substrate, the plurality of micro light-emitting diodes are located on a second side of the substrate, the plurality of connection via holes pass through the substrate and include a plurality of first connection via holes, and the plurality of conductive structures are located in the plurality of connection via holes and include a plurality of first conductive structures, the plurality of first conductive structures are located in the plurality of first connection via holes, and the plurality of micro light-emitting diodes are electrically connected to the driver circuit layer by the plurality of first conductive structures.

The present application claims the priority of the Chinese patent application No. 202310807146.6 filed on Jun. 30, 2023, the disclosure of which is incorporated herein by reference in its entirety as part of the present application.

### TECHNICAL FIELD

The embodiments of the present disclosure relate to a micro light-emitting diode substrate and a manufacturing method thereof.

### BACKGROUND

The liquid crystal display (LCD) technology is the earliest and most mature display technology, while the organic light-emitting diode (OLED) display technology is a new generation of display technology after the LCD, and has been well developed.

In recent years, with the rapid development of the micro light-emitting diode (MLED) industry, the micro light-emitting diode has been increasingly applied widely. The micro light-emitting diode includes the mini light-emitting diodes (mini LED) and the micro light-emitting diode (micro LED), where the micro light-emitting diode has advantageous characteristics such as lower power consumption, faster response, longer life, and higher color saturation and contrast. With technical breakthroughs, the mini LED display and the micro LED display will become the next generation of display technologies after the LCD and the OLED. As the 4K ultra-high-definition display is widely applied in the 5G era, it is expected that conventional panel will be replaced with the mini-LED panel and the micro-LED panel at a higher speed, resulting in a large market potential.

### SUMMARY

The embodiments of the present disclosure provide a micro light-emitting diode substrate and a manufacturing method thereof. The micro light-emitting diode substrate can realize seamless splicing between substrates, reducing splicing seams at splicing place. In addition, yield rate can also be improved in rework of the micro light-emitting diode, and the emission or display of the micro light-emitting diode is also not affected by the growth of foreign matters in the substrate.

At least one embodiment of that present disclosure provides a micro light-emitting diode substrate, including: a substrate; a driver circuit layer, provided on a first side of the substrate; a plurality of micro light-emitting diodes, provided on a second side of the substrate, wherein the second side and the first side are two opposite sides of the substrate; a plurality of connection via holes, passing through the substrate; and a plurality of conductive structures, located in the plurality of connection via holes and arranged in a one-to-one correspondence to the plurality of connection via holes, wherein the plurality of connection via holes include a plurality of first connection via holes, the plurality of conductive structures include a plurality of first conductive structures, the plurality of first conductive structures are located in the plurality of first connection via holes, and the plurality of micro light-emitting diodes are electrically connected to the driver circuit layer through the plurality of first conductive structures.

For example, in the micro light-emitting diode substrate provided by an embodiment of the present disclosure, each of the plurality of micro light-emitting diodes includes a first electrode and a second electrode, an end of each of the plurality of first conductive structures is connected to the driver circuit layer, and another end of each of the plurality of first conductive structures is exposed as a pad on the second side of the substrate, and the pad is configured to be connected to the first electrode or the second electrode.

For example, in the micro light-emitting diode substrate provided by an embodiment of the present disclosure, at least one of the plurality of first connection via holes includes: a first sub-portion; and a second sub-portion, provided on a side of the first sub-portion close to the driver circuit layer, wherein an average hole diameter of the second sub-portion is larger than an average hole diameter of the first sub-portion.

For example, in the micro light-emitting diode substrate provided by an embodiment of the present disclosure, in a direction pointing from the substrate to the driver circuit layer, a hole diameter of the first sub-portion remains constant, a hole diameter of the second sub-portion gradually decreases, and a maximum hole diameter of the second sub-portion is larger than the hole diameter of the first sub-portion.

For example, in the micro light-emitting diode substrate provided by an embodiment of the present disclosure, a cross section of the first sub-portion cut by a plane perpendicular to the substrate includes a rectangle, and a cross section of the second sub-portion cut by a plane perpendicular to the substrate includes a trapezoid.

For example, in the micro light-emitting diode substrate provided by an embodiment of the present disclosure, the substrate includes a base substrate and a first passivation layer, the first sub-portion is located in the base substrate, and the second sub-portion is located in the first passivation layer.

For example, in the micro light-emitting diode substrate provided by an embodiment of the present disclosure, at least one of the plurality of first conductive structures includes: a first conductive portion; a second conductive portion, provided on a side of the first conductive portion close to the driver circuit layer, wherein an average radial dimension of the second conductive portion is greater than an average radial dimension of the first conductive portion.

For example, in the micro light-emitting diode substrate provided by an embodiment of the present disclosure, in a direction pointing from the substrate to the driver circuit layer, a radial dimension of the first conductive portion remains constant, a radial dimension of the second conductive portion gradually decreases, and a maximum radial dimension of the second conductive portion is larger than the radial dimension of the first conductive portion.

For example, in the micro light-emitting diode substrate provided by an embodiment of the present disclosure, a cross section of the first conductive portion cut by a plane perpendicular to the substrate includes a rectangle, and a cross section of the second conductive portion cut by a plane perpendicular to the substrate includes a trapezoid.

For example, in the micro light-emitting diode substrate provided by an embodiment of the present disclosure, the substrate includes a base substrate and a first passivation layer, the first conductive portion is located in the base substrate, and the second conductive portion is located in the first passivation layer.

For example, in the micro light-emitting diode substrate provided by an embodiment of the present disclosure, the driver circuit layer includes a plurality of signal wires and a plurality of connection wires, and each of the plurality of micro light-emitting diodes is connected to a signal wire of the plurality of signal wires through a first conductive structure of the plurality of first conductive structures and a connection wire of the plurality of connection wires.

For example, in the micro light-emitting diode substrate provided by an embodiment of the present disclosure, further including: a plurality of light-emitting units, each of the plurality of light-emitting units including multiple micro light-emitting diodes of the plurality of micro light-emitting diodes; and a plurality of first micro-driver chips, provided in a correspondence to the plurality of light-emitting units, wherein each of the plurality of first micro-driver chips is configured to drive a corresponding light-emitting unit of the plurality of light-emitting units to emit light, wherein the plurality of connection via holes further include a plurality of second connection via holes, the plurality of conductive structures further include a plurality of second conductive structures, the plurality of second conductive structures are located in the plurality of second connection via holes, and the plurality of first micro-driver chips are connected to the driver circuit layer through the plurality of second conductive structures, the plurality of signal wires include a driving voltage wire, a ground wire, an operating voltage wire and a source address wire, each of the plurality of micro light-emitting diodes is connected to the driving voltage wire through a first conductive structure of the plurality of first conductive structures and a connection wire of the plurality of connection wires, each of the plurality of first micro-driver chips is connected to the ground wire, the operating voltage wire, and the source address wire respectively through a second conductive structure of the plurality of second conductive structures and a connection wire of the plurality of connection wires, alternatively, each of the plurality of first micro-driver chips is connected to the ground wire, the operating voltage wire and the source address wire through each of the plurality of second conductive structures respectively, each of the plurality of first micro-driver chips includes an output end, and each of the plurality of micro light-emitting diodes is connected to the output end through a first conductive structure of the plurality of first conductive structures and a connection wire of the plurality of connection wires.

For example, in the micro light-emitting diode substrate provided by an embodiment of the present disclosure, the driver circuit layer includes: a first conductive layer; a second passivation layer, provided on a side of the first conductive layer away from the substrate; an insulating layer, provided on a side of the second passivation layer away from the first conductive layer; a third passivation layer, provided on a side of the insulating layer away from the second passivation layer; a second conductive layer, provided on a side of the third passivation layer away from the insulation layer; and a plurality of first via holes, passing through the second passivation layer, the insulating layer, and the third passivation layer, wherein the first conductive layer includes a plurality of connection wires, the second conductive layer includes a plurality of signal wires, the plurality of micro light-emitting diodes are connected to the plurality of connection wires of the first conductive layer through the plurality of first conductive structures, and the plurality of connection wires of the first conductive layer are connected to the plurality of signal wires of the second conductive layer through the plurality of first via holes.

For example, in the micro light-emitting diode substrate provided by an embodiment of the present disclosure, further including: a plurality of light-emitting units, each of the plurality of light-emitting units including multiple micro light-emitting diodes of the plurality of micro light-emitting diodes; and a plurality of first micro-driver chips, provided in a correspondence to the plurality of light-emitting units, wherein each of the plurality of micro-driver chips is configured to drive a corresponding light-emitting unit of the plurality of light-emitting units to emit light, wherein the plurality of connection via holes further include a plurality of second connection via holes, the plurality of conductive structures further include a plurality of second conductive structures, the plurality of second conductive structures are located in the plurality of second connection via holes, and the plurality of first micro-driver chips are connected to the driver circuit layer through each of the plurality of second conductive structures, the plurality of signal wires include a driving voltage wire, a ground wire, an operating voltage wire, and a source address wire, each of the plurality of micro light-emitting diodes is connected to the driving voltage wire through a first conductive structure of the plurality of first conductive structures and a connection wire of the plurality of connection wires of the first conductive layer, each of the plurality of first micro-driver chips is connected to the ground wire, the operating voltage wire, and the source address wire respectively through a second conductive structure of the plurality of second conductive structures and a connection wire of the plurality of connection wires of the first conductive layer, each of the plurality of first micro-driver chips includes an output end, and each of the plurality of micro light-emitting diodes is connected to the output end through a first conductive structure of the plurality of first conductive structures and a connection wire of the plurality of connection wires.

For example, in the micro light-emitting diode substrate provided by an embodiment of the present disclosure, further including: a plurality of pixel units; and a plurality of second micro-driver chips, provided in a correspondence to the plurality of pixel units, wherein each of the plurality of second micro-driver chips is configured to drive a corresponding pixel unit of the plurality of pixel units for display, wherein the plurality of micro light-emitting diodes include a first micro light-emitting diode, a second micro light-emitting diode, and a third micro light-emitting diode, the first micro light-emitting diode is configured to emit light of a first color, the second micro light-emitting diode is configured to emit light of a second color, and the third micro light-emitting diode is configured to emit light of a third color, and each of the plurality of pixel units includes the first micro light-emitting diode, the second micro light-emitting diode, and the third micro light-emitting diode, the plurality of connection via holes further include a plurality of second connection via holes, the plurality of conductive structures further include a plurality of second conductive structures, the plurality of second conductive structures are located in the plurality of second connection via holes, and the plurality of second micro-driver chips are connected to the driver circuit layer through the plurality of second conductive structures.

For example, in the micro light-emitting diode substrate provided by an embodiment of the present disclosure, the plurality of signal wires include a first signal wire, a second signal wire, a ground wire, an operating voltage wire, and a data wire, each of the plurality of micro light-emitting diodes is connected to the first signal wire or the second signal wire through each of the plurality of first conductive structure and each of the plurality of connection wires of the first conductive layer, each of the plurality second micro-driver chips is connected to the ground wire, the operating voltage wire, and the data wire respectively through each of the plurality second conductive structures and each of the plurality of connection wires of the first conductive layer, the second micro-driver chip includes three output ends, and the three output ends are respectively connected to the first micro light-emitting diode, the second micro light-emitting diode and the third micro light-emitting diode of the corresponding pixel unit of the plurality of pixel units.

For example, in the micro light-emitting diode substrate provided by an embodiment of the present disclosure, further including: a fourth passivation layer, provided on the first side of the substrate and on a side of the driver circuit layer away from the substrate; and a second via hole, passing through the fourth passivation layer to expose the driver circuit layer.

At least one embodiment of that present disclosure provides a display apparatus, including any of the above micro light-emitting diode substrates.

At least one embodiment of that present disclosure provides a manufacturing method of a micro light-emitting diode substrate, including: providing a substrate; forming a driver circuit layer on a first side of the substrate; forming in the substrate a plurality of connection via holes that pass through the substrate; forming a conductive structure within each of the plurality of connection via holes; and forming a plurality of micro light-emitting diodes on a second side of the substrate, wherein the first side and the second side are two opposite sides of the substrate, the plurality of connection via holes include a plurality of first connection via holes, the plurality of conductive structures include a plurality of first conductive structures, the plurality of first conductive structures are located in the plurality of first connection via holes, and the plurality of micro light-emitting diodes are electrically connected to the driver circuit layer through the plurality of first conductive structures.

For example, in the manufacturing method provided by an embodiment of the present disclosure, the providing the substrate includes: providing a base substrate; and forming a passivation layer on a side of the base substrate close to the driver circuit layer.

For example, in the manufacturing method provided by an embodiment of the present disclosure, the forming in the substrate the plurality of connection via holes includes: forming a blind hole in the base substrate by using a laser process; and etching a portion of the base substrate that has not been drilled and the passivation layer along an extending direction of the blind hole through an etching process to form a first sub-portion that passes through the base substrate and a second sub-portion that passes through the passivation layer, wherein each of the plurality of first connection via holes includes the first sub-portion and the second sub-portion.

For example, in the manufacturing method provided by an embodiment of the present disclosure, an average hole diameter of the second sub-portion is larger than an average hole diameter of the first sub-portion.

For example, in the manufacturing method provided by an embodiment of the present disclosure, in a direction pointing from the substrate to the driver circuit layer, a hole diameter of the first sub-portion remains constant, a hole diameter of the second sub-portion gradually decreases, and a maximum hole diameter the second sub-portion is larger than the hole diameter of the first sub-portion.

For example, in the manufacturing method provided by an embodiment of the present disclosure, a cross section of the first sub-portion cut by a plane perpendicular to the substrate includes a rectangle, and a cross section of the second sub-portion cut by a plane perpendicular to the substrate includes a trapezoid.

For example, in the manufacturing method provided by an embodiment of the present disclosure, a thickness diameter of the portion of the base substrate that has not been drilled is in a range of 0.05 mm to 0.15 mm.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic diagram showing the bulge and corrosion of a copper wire caused by the growth of a foreign matter;

FIG. 2 is a schematic diagram showing a splicing of a micro light-emitting diode product;

FIG. 3A is a cross-sectional schematic diagram of a micro light-emitting diode substrate provided in an embodiment of the present disclosure;

FIG. 3B is a cross-sectional schematic diagram of another micro light-emitting diode substrate provided in an embodiment of the present disclosure;

FIG. 3C is a structural cross-sectional schematic diagram of another micro light-emitting diode substrate provided in an embodiment of the present disclosure;

FIG. 4 is a partial structural schematic diagram of a first connection via hole illustrated by FIG. 3A;

FIG. 5 is a partial structural schematic diagram of a first conductive structure illustrated by FIG. 3A;

FIG. 6 is a schematic diagram of drilling a substrate by a laser process provided in an embodiment of the present disclosure;

FIG. 7 is a schematic diagram of etching a hole in a film layer through a dry etching process provided in an embodiment of the present disclosure;

FIG. 8 is a wiring schematic diagram of a micro light-emitting diode substrate provided in an embodiment of the present disclosure;

FIG. 9 is a partial cross-sectional schematic diagram of a micro light-emitting diode substrate illustrated by FIG. 8;

FIG. 10 is a wiring schematic diagram of another micro light-emitting diode substrate provided in an embodiment of the present disclosure;

FIG. 11 is a cross-sectional schematic diagram of a micro light-emitting diode substrate illustrated by FIG. 10;

FIG. 12 is a wiring schematic diagram of another micro light-emitting diode substrate provided in an embodiment of the present disclosure;

FIG. 13 is a cross-sectional schematic diagram of the micro light-emitting diode substrate illustrated by FIG. 12;

FIG. 14 is a schematic diagram of a display apparatus provided in an embodiment of the present disclosure;

FIG. 15A is a structural schematic diagram that shows a process for drilling a substrate by laser;

FIG. 15B is a structural diagram showing a micro light-emitting diode product;

FIG. 16 is a flow chart of a method for manufacturing a micro light-emitting diode substrate provided in an embodiment of the present disclosure;

FIG. 17A to FIG. 17C are flow charts of a method for forming a connection via hole in a substrate provided in an embodiment of the present disclosure;

FIG. 18A to FIG. 18H are flow charts of a method for manufacturing a micro light-emitting diode substrate illustrated by FIG. 8; and

FIG. 19A to FIG. 19L are flow charts of a method for manufacturing a micro light-emitting diode substrate illustrated by FIG. 10.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “including,” “comprising,” etc., are intended to specify that the elements or the objects stated before these terms encompass the elements or the objects and equivalents thereof listed after these terms, but do not preclude the other elements or objects. The phrases “connected”, “connecting”, etc., are not intended to define a physical connection or mechanical connection, but may include an electrical connection, directly or indirectly.

Unless otherwise defined, the features of “parallel”, “vertical” and “identical” used in the embodiments of the present disclosure include the strict sense of “parallel”, “vertical” and “identical”, as well as the situations involving certain errors such as “substantially parallel”, “substantially vertical” and “substantially identical”. For example, the above-mentioned “substantially” can indicate that the difference value of the compared object is within 10% or 5% of the average value of the compared object. When the number of a component or element is not specifically indicated in the following embodiments of the present disclosure, it means that the component or element can be one or more, or can be understood as at least one. “At least one” refers to one or more, and “more than one” refers to at least two. The “arranged in the same layer” in the embodiments of the present disclosure refers to the relationship between multiple film layers formed by the same material after the same step (e.g., a one-step patterning process). Here, “in the same layer” does not always refer to the thickness of multiple film layers being the same or the height of multiple film layers being the same in the cross-sectional view.

The mini LED and micro LED for the backlight display product have been gradually applied to the TV and the electronic sports display, and have been gradually developed into the small-size device such as the tablet. Based on different base substrates, the base substrate for the mini LED and micro LED products may be classified into the glass substrate, the printed circuit board (PCB), and the like. At present, the PCB substrate is used in the mainstream market product, especially the small-size product. However, the glass base substrate does not have problems such as poor heat dissipation, and the glass substrate may also share the wire body with the TFT product, leading to the greater prospect. The mini LED and the micro LED for the display product may be used as the upgrade technology for the LCD and OLED displays, and are gradually being applied in the display product.

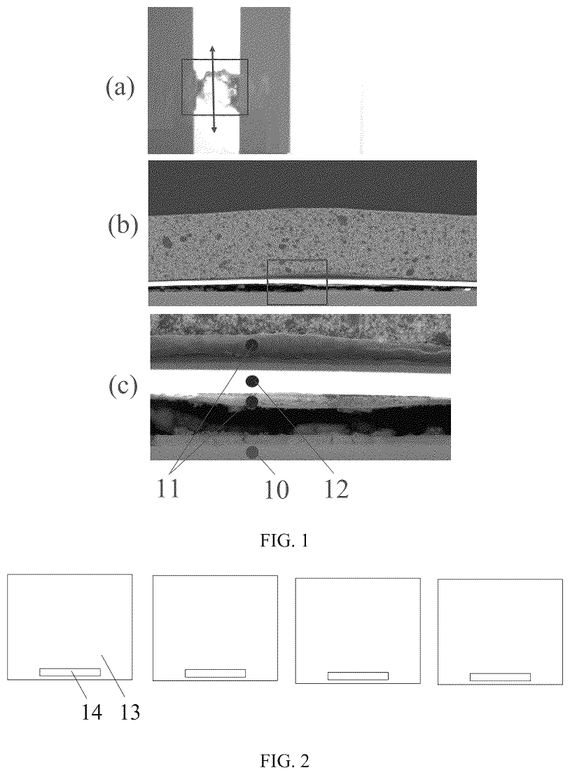

The mini LED and micro LED products are prone to poor reliability problems such as pad corrosion, weak light of the lamp bead, and light out of the lamp bead during long-term reliability test, especially in 8585 O environmental test, which affect product stability. The corrosion problem is mainly caused by the following two main reasons: one is that Na and Ga components in the glass may precipitate and grow, which results in crack, corrosion, and related defects in the film layer; and the other is that growth of foreign matters caused by the introduction of particles in the coating process results in crack, corrosion, and related defects in the film layer, where the growth of both foreign matters described above may lead to the short circuit problem in the circuit. FIG. 1 is a schematic diagram showing the bulge and corrosion of a copper wire caused by the growth of a foreign matter. FIG. 1(b) is a cross-sectional diagram at a frame selection position in FIG. 1(a) taken in a direction along which a copper wire extends, and FIG. 1(c) is a partial enlarged diagram at a frame selection position in FIG. 1(b). As illustrated by FIG. 1, a precipitate 11 of an underlying substrate 10 results in the bulge and corrosion of a copper wire 12, and brings undesirable problems such as short circuit of a circuit and corrosion of a pad.

The mini LED product and the micro LED product are designed to have a driver circuit layer and a micro light-emitting diode located on a same side of the substrate, resulting in the existence of a bonding region on a display side. FIG. 2 is a schematic diagram showing a splicing of a micro light-emitting diode product. As illustrated by FIG. 2, because a display side 13 of a micro light-emitting diode product has a bonding region 14, it is not possible to provide the seamless splicing in each direction, and instead, the seamless splicing may only be provided in the left direction and the right direction.

Embodiments of the present disclosure provide a micro light-emitting diode substrate and a manufacturing method thereof. The micro light-emitting diode substrate includes a substrate, a driver circuit layer, a plurality of micro light-emitting diodes, a plurality of connection via holes, and a plurality of conductive structures. The driver circuit layer is provided on a first side of the substrate, and the plurality of micro light-emitting diodes are provided on a second side of the substrate, the second side and the first side are opposite to each other. The plurality of connection via holes pass through the substrate, and the plurality of conductive structures are located in the plurality of connection via holes, and are arranged in a one-to-one correspondence with the plurality of connection via holes. The plurality of connection via holes include a plurality of first connection via holes, the plurality of conductive structures include a plurality of first conductive structures, the plurality of first conductive structures are located in the plurality of first connection via holes, and the plurality of micro light-emitting diodes are electrically connected to the driver circuit layer through the plurality of first conductive structures.

In the micro light-emitting diode substrate provided in the embodiments of the present disclosure, the driver circuit layer and the micro light-emitting diode are provided on two sides of the substrate, the side on which the micro light-emitting diode is provided is a display side, and the side on which the driver circuit layer is provided is a non-display side, such that a bonding region is also located on the non-display side, thereby providing the seamless splicing of the substrates, reducing the splicing seam at the splicing place, and improving the display effect after the splicing. Compared with the conventional die bonding structure, the micro light-emitting diode is fixed on the substrate through the first conductive structure in the first connection via hole, the less copper the first conductive structure is thinned in the rework of the micro light-emitting diode, and improves the yield rate in the second die bonding process. In addition, in the rework process, the first connection via hole provides a flow leveling effect, which concentrate more copper in the first connection via hole, so that the less copper the first conductive structure is thinned in the rework process, thereby further improving the yield rate. The micro light-emitting diode on the display side is directly assembled on the display side of the substrate, and the driver circuit layer is provided on the non-display side, so that the growth of the foreign matters in the substrate does not affect the light-emitting or display of the micro light-emitting diode, which may improve the corrosion resistance and other performance of the product. The micro light-emitting diode and the driver circuit layer are provided on two sides of the substrate, which reduces the overall voltage and current, thereby also improving the corrosion problem of the wire. In addition, providing the micro light-emitting diode and the driver circuit layer on two sides of the substrate can result in a relatively large layout space of the micro light-emitting diode, thereby improving density of the micro light-emitting diode. It should be noted that the “micro light-emitting diode” herein is not encapsulated and not a common single light-emitting diode, and instead, it only includes a PN junction, a light-emitting layer and another auxiliary light-emitting functional layer.

The following describes a micro light-emitting diode substrate and a manufacturing method thereof provided in the embodiments of the present disclosure with reference to the attached drawings.

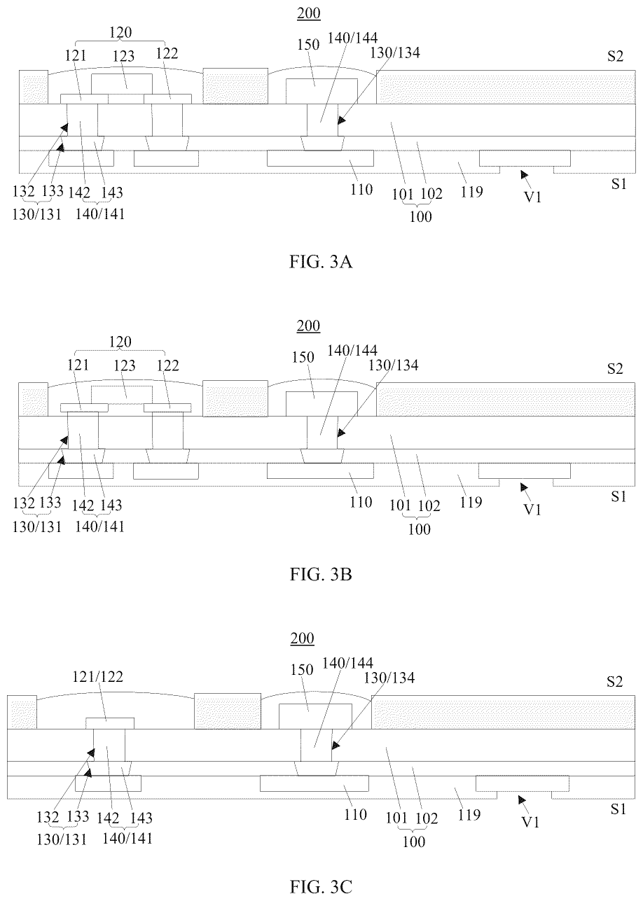

A micro light-emitting diode substrate is provided in an embodiment of the present disclosure. FIG. 3A is a cross-sectional schematic diagram of a micro light-emitting diode substrate provided in an embodiment of the present disclosure. As illustrated by FIG. 3A, the micro light-emitting diode substrate 200 includes a substrate 100, a driver circuit layer 110, a plurality of micro light-emitting diodes 120, a plurality of connection via holes 130, and a plurality of conductive structures 140. The driver circuit layer 110 is provided on a first side S1 of the substrate 100, and the plurality of micro light-emitting diodes 120 are provided on a second side S2 of the substrate 100, the second side S2 and the first side S1 are opposite to each other. The plurality of connection via holes 130 pass through the substrate 100, and the plurality of conductive structures 140 are located in the plurality of connection via holes 130, and are arranged in a one-to-one correspondence with the plurality of connection via holes 130. The plurality of connection via holes 130 include a plurality of first connection via holes 131, the plurality of conductive structures 140 include a plurality of first conductive structures 141, the plurality of first conductive structures 141 are located in the plurality of first connection via holes 131, and the plurality of micro light-emitting diodes 120 are electrically connected to the driver circuit layer 110 through the plurality of first conductive structures 141.

In the micro light-emitting diode substrate provided in the embodiments of the present disclosure, the driver circuit layer 110 and the micro light-emitting diode 120 are provided on two sides of the substrate 100, the side on which the micro light-emitting diode 120 is provided is a display side, and the side on which the driver circuit layer 110 is provided is a non-display side, such that a bonding region is also located on the non-display side, thereby realizing the seamless splicing between the substrates 100, reducing the splicing seam at the splicing place, and improving the display effect after the splicing. Compared with the conventional design where the micro light-emitting diode 120 is fixed through a pad on a copper wire, the micro light-emitting diode 120 is fixed on the substrate 100 through the first conductive structure 141 in the first connection via hole 131, the less copper the first conductive structure is thinned in the rework of the micro light-emitting diode, and improves the yield rate in the second die bonding process. In addition, in the rework process, the first connection via hole 131 provides a flow leveling effect, which concentrate more copper in the first connection via hole 131, so that the less copper the first conductive structure 141 is thinned in the rework process, thereby further improving the yield rate. The micro light-emitting diode 120 on the display side is directly assembled on the display side of the substrate 100, and the driver circuit layer 110 is provided on the non-display side, so that the growth of foreign matters in the substrate does not affect the light-emitting or display of the micro light-emitting diode 120, which may improve the corrosion resistance and other performance of the product. The micro light-emitting diode 120 and the driver circuit layer 110 are provided on two sides of the substrate 100, which reduces the overall voltage and current, thereby also improving the corrosion problem of the wire. In addition, providing the micro light-emitting diode 120 and the driver circuit layer 110 on two sides of the substrate 100 may result in a relatively large layout space of the micro light-emitting diode 120, thereby improving density of the micro light-emitting diode 120.

For example, the “micro light-emitting diode 120” herein may be not encapsulated and only include a PN junction, a light-emitting layer and another auxiliary light-emitting functional layer. It may be apartment that this is not limited in the embodiments of the present disclosure.

In some examples, as illustrated by FIG. 3A, each micro light-emitting diode 120 includes a first electrode 121 and a second electrode 122, and the first electrode 121 and the second electrode 122 are respectively connected to the driver circuit layer 110 through different first conductive structures 141. For example, each micro light-emitting diode 120 also includes a light-emitting functional layer 123.

FIG. 3B is a cross-sectional schematic diagram of another micro light-emitting diode substrate provided in an embodiment of the present disclosure. As illustrated by FIG. 3B, each micro light-emitting diode 120 includes the first electrode 121 and the second electrode 122, one end of each first conductive structure 141 is connected to the driver circuit layer 110, and another end of each first conductive structure 141 is exposed as a pad on the second side S2 of the substrate 100, the pad is configured to be connected to the first electrode or the second electrode of the micro light-emitting diode 120. Therefore, the micro light-emitting diode 120 may be connected to the first conductive structure 141 more easily and more effectively, improving the die bonding efficiency and die bonding yield of the micro light-emitting diode 120.

FIG. 3C is a structural cross-sectional schematic diagram of another micro light-emitting diode substrate provided in an embodiment of the present disclosure. As illustrated by FIG. 3C, a section line only cuts the first electrode 121 or the second electrode 122 of the micro light-emitting diode 120, and the micro light-emitting diode 120 shows only one first electrode 121 or one second electrode 122 connected to the first conductive structure 141.

In some examples, as illustrated by FIG. 3A to FIG. 3C, at least one of the plurality of first connection via holes 131 includes a first sub-portion 132 and a second sub-portion 133. The second sub-portion 133 is provided on a side of the first sub-portion 132 close to the driver circuit layer 110, an average hole diameter of the second sub-portion 133 is greater than an average hole diameter of the first sub-portion 132, improving contact adhesive force between the first conductive structure 141 in the first connection via hole 131 and the driver circuit layer 110, and further improving the performance stability. In this case, the first connection via hole 131 may have an overall cross section shaped like a ship anchor, and the first conductive structure 141 located in the first connecting via hole 131 may have an overall cross section shaped like a ship anchor, the anchor-shaped design of the first connection via hole 131 and the first conductive structure 141 can improve the contact adhesive force between the first conductive structure 141 in the first connection via hole 131 and the driver circuit layer 110, improving the performance stability.

In some examples, as illustrated by FIG. 3A to FIG. 3C, in a direction pointing from the substrate 100 to the driver circuit layer 110, a hole diameter of the first sub-portion 132 remains substantially constant, a hole diameter of the second sub-portion 133 gradually decreases, and a maximum hole diameter of the second sub-portion 133 is larger than the hole diameter of the first sub-portion 132. So that, the first connection via hole 131 may be shaped like the ship anchor, the first conductive structure 141 located in the first connection via hole 131 may be shaped like the ship anchor, and the anchor-shaped design of the first connection via hole 131 and the first conductive structure 141 can improve the contact adhesive force between the first conductive structure 141 in the first connection via hole 131 and the driver circuit layer 110, improving the performance stability.

In some examples, as illustrated by FIG. 3A to FIG. 3C, a cross section of the first sub-portion 132 cut by a plane perpendicular to the substrate 100 includes a rectangle, and a cross section of the second sub-portion 133 cut by a plane perpendicular to the substrate 100 includes a trapezoid, a bottom edge of the trapezoid is connected with the rectangle.

In some examples, as illustrated by FIG. 3A to FIG. 3C, the substrate 100 includes a base substrate 101 and a first passivation layer 102, the first sub-portion 132 is provided in the base substrate 101, and the second sub-portion 133 is provided in the first passivation layer 102. The first sub-portion 132 is a via hole formed in the base substrate 101, and the second sub-portion 133 is a via hole formed in the first passivation layer 102.

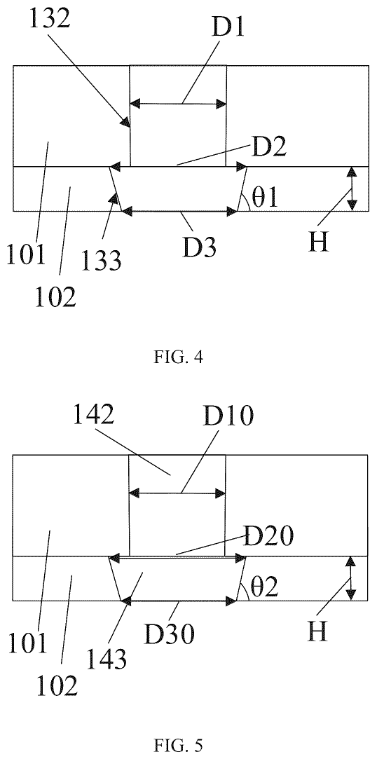

FIG. 4 is a partial structural schematic diagram of a first connection via hole illustrated by FIG. 3A. As illustrated by FIG. 3A and FIG. 4, the hole diameter of the first sub-portion 132 is D1, the maximum hole diameter of the second sub-portion 133 is D2, a minimum hole diameter of the second sub-portion 133 is D3, a thickness of the first passivation layer 102 is H, and an included angle between a side edge of the second sub-portion 133 and a bottom surface of the base substrate 101 is θ1. For example, D1 and D3 may have a relationship that meets: D3≥D1. For example, D1, D2, and D3 may have a relationship that meets: D2≥D3+2H/tanθ1. It may be apparent that the first connection via hole in FIG. 3B and FIG. 3C also meets the above relationship, which will not be described again here.

In some examples, as illustrated by FIG. 3A to FIG. 3C, at least one of the plurality of first conductive structures 141 includes a first conductive portion 142 and a second conductive portion 143, the second conductive portion 143 is located on a side of the first conductive portion 142 close to the driver circuit layer 110. An average radial dimension of the second conductive portion 143 is greater than an average radial dimension of the first conductive portion 142. So that the first conductive structure 141 may be shaped like a ship anchor, thereby improving the contact adhesive force between the first conductive structure 141 and the driver circuit layer 110 and the performance stability.

In some examples, as illustrated by FIG. 3A to FIG. 3C, in the direction pointing from the substrate 100 to the driver circuit layer 110, the radial dimension of the first conductive portion 142 remains substantially constant, and the radial dimension of the second conductive portion 143 gradually decreases, and a maximum radial dimension of the second conductive portion 143 is larger than the radial dimension of the first conductive portion 142. So that the first conductive structure 141 may be shaped like a ship anchor, thereby improving the contact adhesive force between the first conductive structure 141 and the driver circuit layer 110 and the performance stability.

In some examples, as illustrated by FIG. 3A to FIG. 3C, a cross section of the first conductive portion 142 cut by a plane perpendicular to the substrate 100 includes a rectangle, and a cross section of the second conductive portion 143 cut by a plane perpendicular to the substrate 100 includes a trapezoid, a bottom edge of the trapezoid is connected with the rectangle.

In some examples, as illustrated by FIG. 3A to FIG. 3C, the substrate 100 includes the base substrate 101 and the first passivation layer 102, the first conductive portion 142 is provided in a via hole in the base substrate 101. For example, the via hole is the first sub-portion 132. The second conductive portion 143 is provided in a via hole in the first passivation layer 102. For example, the via hole is the second sub-portion 133.

FIG. 5 is a partial structural schematic diagram of a first conductive structure illustrated by FIG. 3A. As illustrated by FIG. 3A and FIG. 5, the radial dimension of the first conductive portion 142 is D10, the maximum radial dimension of the second conductive portion 143 is D20, a minimum radial dimension of the second conductive portion 143 is D30, a thickness of the first passivation layer 102 is H, and an included angle between a side edge of the second conductive portion 143 and the bottom surface of the base substrate 101 is θ2. For example, D10 and D30 may have a relationship that meets: D30≥D10. For example, D10, D20, and D30 may have a relationship that meets: D20≥D30+2H/tanθ2. It may be apparent that the first conductive structure in FIG. 3B and FIG. 3C also meets the above relationship, which will not be described again here.

In some examples, as illustrated by FIG. 4 and FIG. 5, the hole diameter D1 of the first sub-portion 132 is equal to the radial dimension D10 of the first conductive portion 142, the maximum hole diameter D2 of the second sub-portion 143 is equal to the maximum radial dimension D20 of the second conductive portion 143, the minimum hole diameter D3 of the second sub-portion 143 is equal to the minimum radial dimension D30 of the second conductive portion 143, and the included angle θ1 between the side edge of the second sub-portion 133 and the bottom surface of the base substrate 101 is larger than the included angle 02 between the side edge of the second conductive portion 143 and the bottom surface of the base substrate 101.

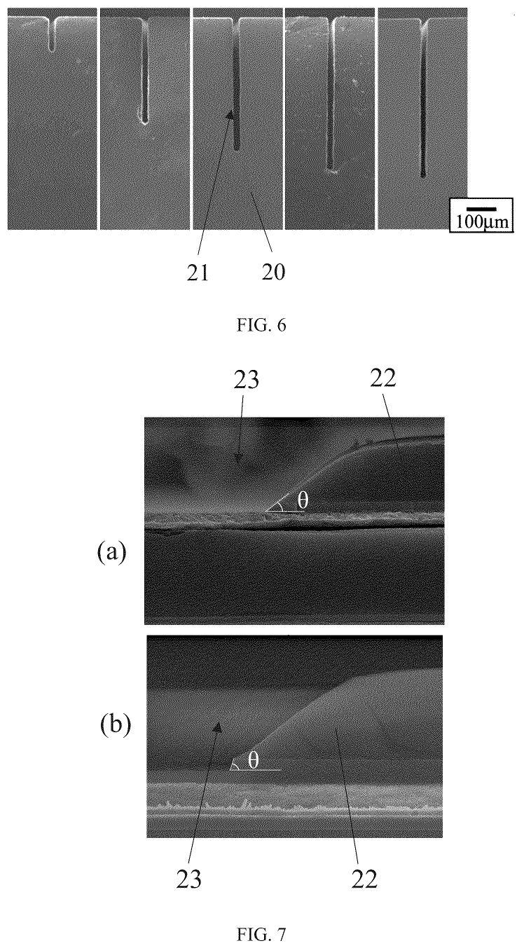

FIG. 6 is a schematic diagram of drilling a substrate by a laser process provided in an embodiment of the present disclosure. As illustrated by FIG. 6, it may be seen from left to right that when a substrate 20 is drilled by the laser process, a contour of a hole 21 keeps substantially the same as a depth of the hole 21 increases, and a side edge of the hole 21 is substantially perpendicular to a surface of the substrate 20. In this way, the first sub-portion 132 of the first connection via hole 131 described above may be formed in the substrate by the laser process. It may be apparent that the process for forming the first sub-portion 132 is not limited in the embodiments of the present disclosure.

FIG. 7 is a schematic diagram of etching a hole in a film layer through a dry etching process provided in an embodiment of the present disclosure. As illustrated by FIG. 7(a), when a film layer 22 is etched by the dry etching process, a dry etching parameter may be adjusted so that an included angle θ between a contour of a hole 23 and a bottom surface of the film layer 22 is approximately 30 degrees, and as illustrated by FIG. 7(b), the included angle θ between the contour of the hole 23 and the bottom surface of the film layer 22 is approximately 80 degrees, so that the value of the included angle θ between the contour of the hole 23 and the bottom surface of the film layer 22 may be adjusted between 30 degrees and 80 degrees, the included angle corresponds to the included angle θ1 in the preceding embodiment. Therefore, the second sub-portion 133 of the first connection via hole 131 described above may be formed by the dry etching process, and holes of different contours may be etched according to design requirements. It may be apparent that the process for forming the second sub-portion 133 is not limited in the embodiments of the present disclosure.

For example, as illustrated by FIG. 3A to FIG. 3C, FIG. 6 and FIG. 7, the laser process may be used to first form a blind hole in the base substrate 101, and then a portion of the base substrate 101 that has not been drilled and the first passivation layer 102 may be etched by the etching process to form the first sub-portion 132 in the base substrate 101 and the second sub-portion 133 in the first passivation layer 102.

In some examples, as illustrated by FIG. 3A to FIG. 3C, the micro light-emitting diode substrate further includes a plurality of micro-driver chips 150, each of the plurality of micro-driver chips is configured to drive the corresponding micro light-emitting diode 120 to emit light or display. The plurality of connection via holes 130 further include a plurality of second connection via holes 134, the plurality of conductive structures 140 further include a plurality of second conductive structures 144, the plurality of second conductive structures 144 are located in the plurality of second connection via holes 134, and the plurality of micro light-emitting diodes 150 are connected to the driver circuit layer 110 through the plurality of second conductive structures 144. The micro-driver chip 150 on the display side is directly assembled on the display side of the substrate 100, and the driver circuit layer 110 is provided on the non-display side, so that the growth of foreign matters does not affect the micro-driver chip 150, which can improve the corrosion resistance and other performance of the product. In addition, the micro-driver chip 150 and the micro light-emitting diode 120 are provided on a same side of the substrate 100, which also facilitates the assembly of the micro-driver chip 150 and the micro light-emitting diode 120. It should be noted that the second connection via hole 134 may further include the first sub-portion 132 and the second sub-portion 133, and the second conductive structure 144 may further include the first conductive portion 142 and the second conductive portion 143. The second connection via hole 134 has a same design for parameters such as a dimension as that of the first connection via hole 131, and the second conductive structure 144 has a same design for parameters such as a dimension as that of the first conductive structure 141, so that the second conductive structure 144 may have the same beneficial effect as the first conductive structure 141, which will not be described again herein. It should be noted that FIG. 3A to FIG. 3C only schematically show that the micro-driver chip 150 is connected to the second conductive structure 144. For example, the micro-driver chip 150 may include a plurality of terminals. For example, the plurality of terminals include a plurality of input terminals and a plurality of output ends. The plurality of terminals of the micro-driver chip 150 are connected to the second conductive structure 144 to further connect to the driver circuit layer 110.

In some examples, as illustrated by FIG. 3A to FIG. 3C, the micro light-emitting diode substrate further includes a passivation layer 119 and a via hole V1. The passivation layer 119 is provided on the first side S1 of the substrate 100, and is provided on a side of the driver circuit layer 110 away from the substrate 100, and the via hole V1 passes through the passivation layer 119 to expose the driver circuit layer 110. In this way, a driver circuit board and a flexible circuit board may be arranged on the first side S1 of the substrate 100, that is, the non-display side, an end of the flexible circuit board may be connected to the driver circuit layer 110 through the via hole V1, and another end of the flexible circuit board is connected to the driver circuit board, thereby realizing the seamless splicing between the substrates 100, reducing the splicing seams at the splicing place, and improving the display effect after splicing.

In some examples, the substrate 100 includes, but is not limited to, a glass substrate, a printed circuit board, a resin substrate, and the like. For example, base substrate 101 includes, but is not limited to, a glass substrate, or the like.

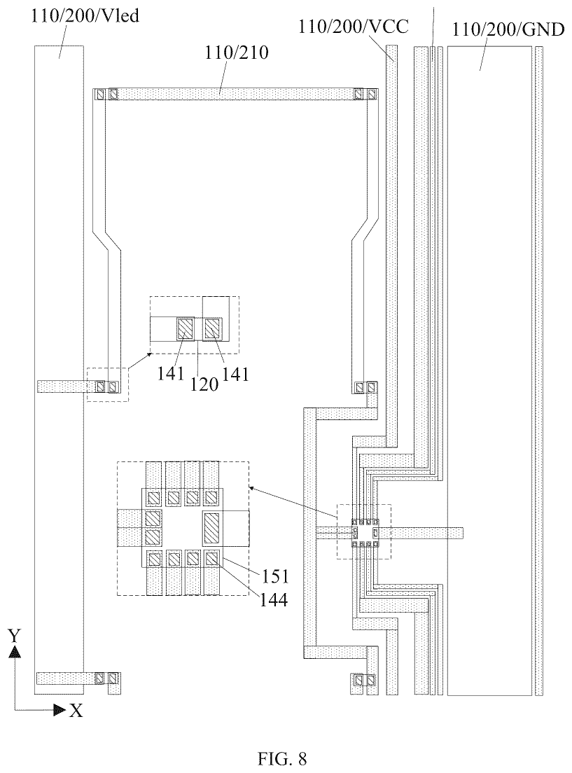

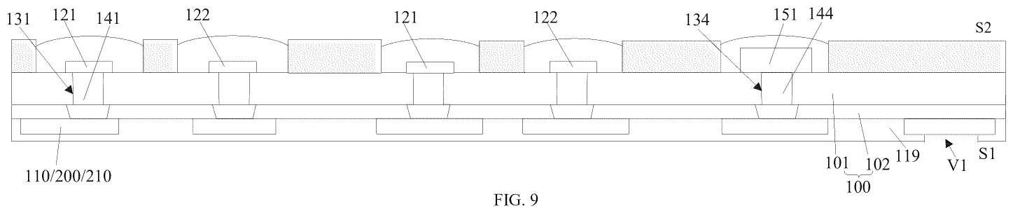

FIG. 8 is a wiring schematic diagram of a micro light-emitting diode substrate provided in an embodiment of the present disclosure, and FIG. 9 is a partial cross-sectional schematic diagram of a micro light-emitting diode substrate illustrated by FIG. 8. As illustrated by FIG. 8 and FIG. 9, the driver circuit layer 110 of the micro light-emitting diode substrate includes a plurality of signal wires 200 and a plurality of connection wires 210, and the micro light-emitting diode 120 is connected to the signal wire 200 through the first conductive structure 141 and the connection wire 210. Therefore, the signal wire 200 can provide a signal for the micro light-emitting diode 120 and the micro light-emitting diode 120 can emit light. For example, the micro light-emitting diode substrate may be applied in a backlight module of a display apparatus.

In some examples, as illustrated by FIG. 8 and FIG. 9, the micro light-emitting diode substrate further includes a plurality of light-emitting units and a plurality of first micro-driver chips 151, each of the plurality of light-emitting units includes multiple micro light-emitting diodes 120, the plurality of first micro-driver chips 151 are provided in a correspondence to the plurality of light-emitting units, and each of the plurality of first micro-driver chips 151 is configured to drive the corresponding light-emitting unit to emit light. Thus, the light-emitting unit can be driven by the corresponding micro-driver chip to emit light.

In some examples, as illustrated by FIG. 8 and FIG. 9, the plurality of connection via holes 130 further include the plurality of second connection via holes 134, the plurality of conductive structures 140 further include the plurality of second conductive structures 144, the plurality of second conductive structures 144 are located in the plurality of second connection via holes 134, and the plurality of first micro-driver chips 151 are connected to the driver circuit layer 110 through the plurality of second conductive structures 144.

In some examples, as illustrated by FIG. 8, the plurality of signal wires 200 include a driving voltage wire Vled, a ground wire GND, an operating voltage wire VCC, and a source address wire ADDR, and the like. For example, the plurality of signal wires 200 may extend in a second direction Y.

In some examples, as illustrated by FIG. 8, the plurality of connection wires 210 may extend in the first direction X or in the second direction Y.

In some examples, as illustrated by FIG. 8, each of the plurality of light-emitting units includes four micro light-emitting diodes 120, and the four micro light-emitting diodes 120 are connected in series through a connection wire 210 extending in the first direction X and two connection wires 210 extending in the second direction Y in a first conductive layer 112. It may be apparent that the embodiments of the present disclosure do not limit the number of micro light-emitting diodes 120 included in the light-emitting units, and also do not limit the mode of connecting the plurality of micro light-emitting diodes 120 included in each of the plurality of light-emitting units in series or in parallel.

In some examples, as illustrated by FIG. 8, the micro light-emitting diode 120 of the light-emitting unit is connected to the driving voltage wire Vled through the first conductive structure 141 and the connection wire 210.

In some examples, as illustrated by FIG. 9, each of the micro light-emitting diodes 120 includes the first electrode 121 and the second electrode 122, and the first electrode 121 and the second electrode 122 are respectively connected to the first conductive structures 141. For example, an end of the first conductive structure 141 is exposed on the second side S2 of the substrate 100 to be used as a pad. It may be apparent that this is not limited in the present disclosure.

In some examples, as illustrated by FIG. 8, the first micro-driver chip 151 is connected to the operating voltage wire VCC and the source address wire ADDR through the second conductive structures 144, respectively, and the first micro-driver chip 151 is connected to the ground wire GND through the second conductive structure 144 and the connection wire 210. It may be apparent that the embodiments of the present disclosure do not limit the mode of connecting the first micro-driver chip 151 to the ground wire GND, the operating voltage wire VCC and the source address wire ADDR, they may be directly connected through the second conductive structure 144, and may also be connected through the second conductive structure 144 and the connection wire 210.

In some examples, as illustrated by FIG. 8, the first micro-driver chip 151 further includes an output end, and the micro light-emitting diode 120 is connected to the output end through the first conductive structure 141 and the connection wire 210.

In some examples, as illustrated by FIG. 8, multiple micro light-emitting diodes 120 of the light-emitting unit are provided between the driving voltage wire Vled and the ground wire GND. For example, the first micro-driver chip 151 is provided between the driving voltage wire Vled and the ground wire GND. For example, multiple micro light-emitting diodes 120 of the light-emitting unit are provided between the driving voltage wire Vled and the first micro-driver chip 151 in a direction perpendicular to the driving voltage wire Vled.

In some examples, as illustrated by FIG. 9, the micro light-emitting diode substrate further includes the passivation layer 119 and the via hole V1. The passivation layer 119 is provided on the first side S1 of the substrate 100, and is provided on a side of the driver circuit layer 110 away from the substrate 100. Therefore, the driver circuit board and the flexible circuit board may be arranged on the first side S1 of the substrate 100, that is, the non-display side, an end of the flexible circuit board may be connected to the driver circuit layer 110 through the via hole V1, and another end of the flexible circuit board is connected to the driver circuit board, thereby realizing the seamless splicing between the substrates 100, reducing splicing seams at the splicing place, and improving the display effect after splicing.

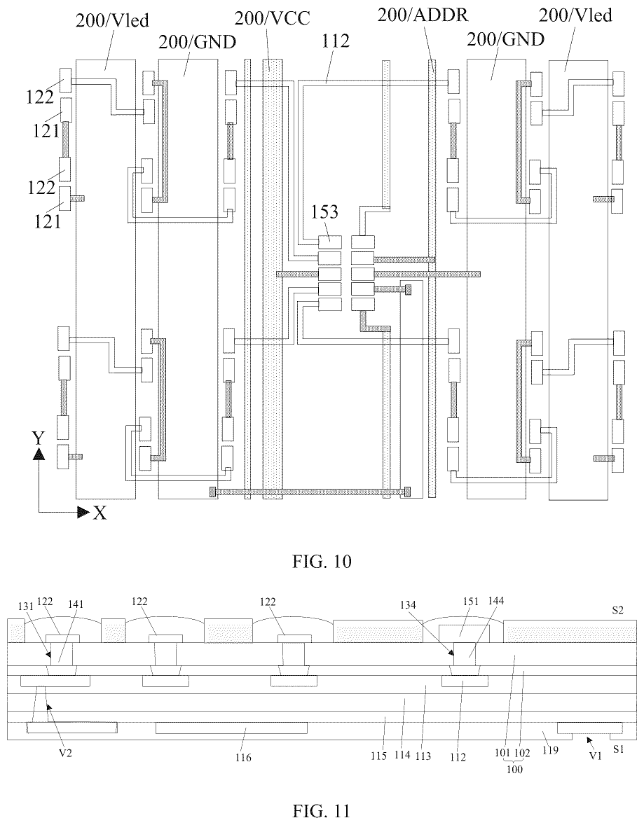

FIG. 10 is a wiring schematic diagram of another micro light-emitting diode substrate provided in an embodiment of the present disclosure, and FIG. 11 is a cross-sectional schematic diagram of a micro light-emitting diode substrate illustrated by FIG. 10. As illustrated by FIG. 10 and FIG. 11, the driver circuit layer 110 of the micro light-emitting diode substrate includes a first conductive layer 112, a second passivation layer 113, an insulating layer 114, a third passivation layer 115, a second conductive layer 116 and a plurality of via holes V2. The second passivation layer 113 is provided on a side of the first conductive layer 112 away from the substrate 100, the insulating layer 114 is provided on a side of the second passivation layer 113 away from the first conductive layer 112, the third passivation layer 115 is provided on a side of the insulating layer 114 away from the second passivation layer 113, and the second conductive layer 116 is provided on a side of the third passivation layer 115 away from the insulating layer 114; and the plurality of via holes V2 pass through the second passivation layer 113, the insulating layer 114, and the third passivation layer 115. The first conductive layer 112 includes a plurality of connection wires 210, the second conductive layer 116 includes a plurality of signal wires 200, the plurality of micro light-emitting diodes 120 are connected to the plurality of connection wires 210 of the first conductive layer 112 through the plurality of first conductive structures 141, and the first conductive layer 112 is connected to the plurality of signal wires 200 of the second conductive layer 116 through the plurality of via holes V2. For example, the micro light-emitting diode substrate may be applied in products with more complex circuits and higher density of micro light-emitting diodes 120. For example, the micro light-emitting diode substrate may be applied in a backlight module of a display apparatus. It should be noted that FIG. 10 shows only the first electrode 121 and the second electrode122 of the micro light-emitting diode 120.

In some examples, as illustrated by FIG. 10 and FIG. 11, the micro light-emitting diode substrate further includes the plurality of light-emitting units and the plurality of first micro-driver chips 151, each of the plurality of light-emitting units includes multiple micro light-emitting diodes 120, the plurality of first micro-driver chips 151 are provided in a correspondence to the plurality of light-emitting units, and each of the plurality of micro-driver chips is configured to drive the corresponding light-emitting unit to emit light. It should be noted that FIG. 10 shows only terminals of the first micro-driver chip 151.

In some examples, as illustrated by FIG. 11, the plurality of connection via holes 130 further include the plurality of second connection via holes 134, the plurality of conductive structures 140 further include the plurality of second conductive structures 144, the plurality of second conductive structures 144 are located in the plurality of second connection via holes 134, and the plurality of first micro-driver chips 151 are connected to the driver circuit layer 110 through the plurality of second conductive structures 144.

In some examples, as illustrated by FIG. 10, the plurality of signal wires 200 include the driving voltage wire Vled, the ground wire GND, the operating voltage wire VCC, and the source address wire ADDR. For example, the plurality of signal wires 200 may extend in a second direction Y.

In some examples, as illustrated by FIG. 10, the plurality of connection wires 210 may extend in the first direction X or in the second direction Y.

In some examples, as illustrated by FIG. 10, each of the plurality of light-emitting units includes six micro light-emitting diodes 120, and the six micro light-emitting diodes 120 are connected in series through multiple connection wires 112 extending in the first direction X and multiple connection wires 112 extending in the second direction Y in first conductive layer 112. It may be apparent that the embodiments of the present disclosure do not limit the number of micro light-emitting diodes 120 included in the light-emitting units, and also do not limit the mode of connecting the plurality of micro light-emitting diodes 120 included in each of the plurality of light-emitting units in series or in parallel.

In some examples, as illustrated by FIG. 10 and FIG. 11, the micro light-emitting diode 120 of the light-emitting unit is connected to the driving voltage wire Vled of the second conductive layer 116 through the first conductive structure 141 and the connection wires 112 of the first conductive layer 112.

In some examples, as illustrated by FIG. 10 and FIG. 11, the first micro-driver chip 151 is connected to the ground wire GND, the operating voltage wire VCC, and the source address wire ADDR through the second conductive structures 144 and the connection wires 112 of the first conductive layer 112, respectively.

In some examples, as illustrated by FIG. 10 and FIG. 11, the first micro-driver chip 151 further includes at least one output end 153, and the micro light-emitting diode 120 is connected to the output end through the first conductive structure 141 and the connection wire 112 of the first conductive layer 112.

In some examples, as illustrated by FIG. 10, the first micro-driver chip 151 corresponds to four groups of light-emitting units and controls the four groups of light-emitting units to emit light.

In some examples, as illustrated by FIG. 10, the micro light-emitting diode substrate further includes the passivation layer 119 and the via hole V1. The passivation layer 119 is provided on the first side S1 of the substrate 100, and is provided on a side of the driver circuit layer 110 away from the substrate 100. Therefore, the driver circuit board and the flexible circuit board may be arranged on the first side S1 of the substrate 100, that is, the non-display side, an end of the flexible circuit board may be connected to the second conductive layer 116 through the via hole V1, and another end of the flexible circuit board is connected to the driver circuit board, thereby realizing the seamless splicing between the substrates 100, reducing splicing seams at the splicing place, and improving the display effect after splicing.

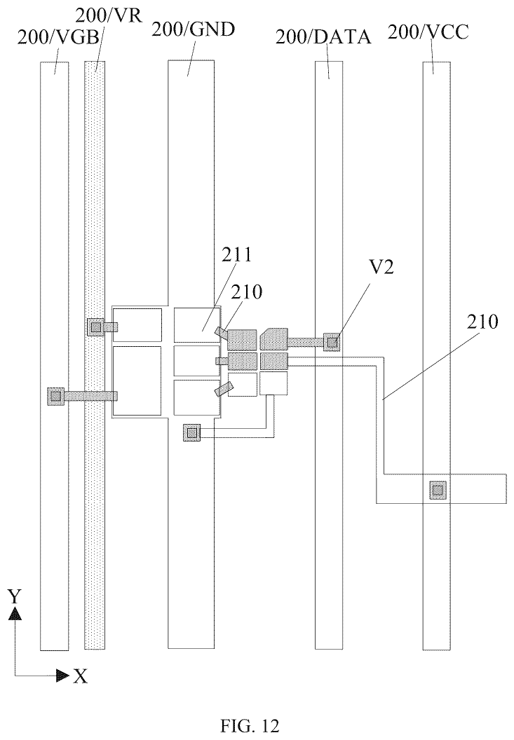

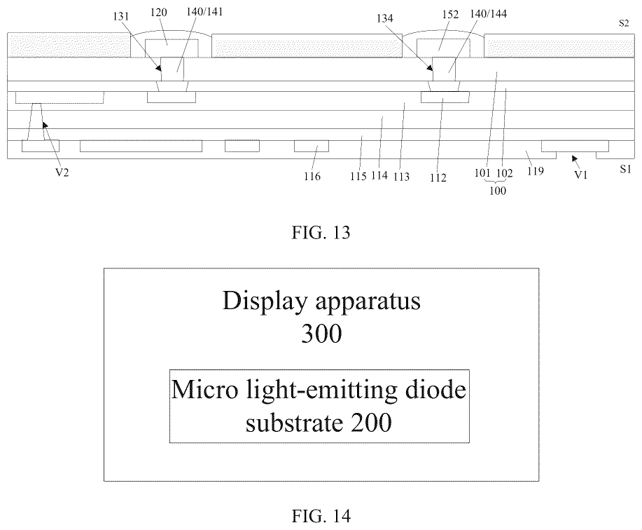

FIG. 12 is a wiring schematic diagram of another micro light-emitting diode substrate provided in an embodiment of the present disclosure, and FIG. 13 is a cross-sectional schematic diagram of the micro light-emitting diode substrate illustrated by FIG. 12. As illustrated by FIG. 12 and FIG. 13, a driver circuit layer 110 of the micro light-emitting diode substrate includes a first conductive layer 112, a second passivation layer 113, an insulating layer 114, a third passivation layer 115, a second conductive layer 116 and a plurality of via holes V2. The second passivation layer 113 is provided on a side of the first conductive layer 112 away from the substrate 100, the insulating layer 114 is provided on a side of the second passivation layer 113 away from the first conductive layer 112, the third passivation layer 115 is provided on a side of the insulating layer 114 away from the second passivation layer 113, and the second conductive layer 116 is provided on a side of the third passivation layer 115 away from the insulating layer 114; and the plurality of via holes V2 pass through the second passivation layer 113, the insulating layer 114, and the third passivation layer 115. The first conductive layer 112 includes a plurality of connection wires 210, the second conductive layer 116 includes a plurality of signal wires 200, the plurality of micro light-emitting diodes 120 are connected to the plurality of connection wires 210 of the first conductive layer 112 through the plurality of first conductive structures 141, and the first conductive layer 112 is connected to the plurality of signal wires 200 of the second conductive layer 116 through the plurality of via holes V2. For example, the micro light-emitting diode substrate may be applied in direct display products.

In some examples, as illustrated by FIG. 12 and FIG. 13, the micro light-emitting diode substrate further includes a plurality of pixel units and a plurality of second micro-driver chips 152. The plurality of second micro-driver chips 152 are provided in a correspondence with the plurality of pixel units, and each of the plurality of second micro-driver chips 152 is configured to drive the corresponding pixel unit for display.

In some examples, as illustrated by FIG. 12 and FIG. 13, the plurality of micro light-emitting diodes 120 include a first micro light-emitting diode, a second micro light-emitting diode, and a third micro light-emitting diode, the first micro light-emitting diode is configured to emit light of a first color, the second micro light-emitting diode is configured to emit light of a second color, and the third micro light-emitting diode is configured to emit light of a third color, and each pixel unit includes the first micro light-emitting diode, the second micro light-emitting diode, and the third micro light-emitting diode. It should be noted that the first color, the second color, and the third color are different from each other. For example, the first color is green, the second color is red, and the third color is blue. It may be apparent that the present disclosure includes, but is not limited to, this, and the first color, the second color, and the third color described above may also be other colors.

In some examples, as illustrated by FIG. 12 and FIG. 13, the plurality of connection via holes 130 further include a plurality of second connection via holes 134, the plurality of conductive structures 140 further include a plurality of second conductive structures 144, the plurality of second conductive structures 144 are located in the plurality of second connection via holes 134, and the plurality of second micro-driver chips 152 are connected to the driver circuit layer 110 through the plurality of second conductive structures 144.

In some examples, as illustrated by FIG. 12, the plurality of signal wires 200 include a first signal wire VR, a second signal wire VGB, a ground wire GND, an operating voltage wire VCC, and a source data wire DATA. For example, the plurality of signal wires 200 may extend in the second direction Y.

In some examples, as illustrated by FIG. 12, the plurality of connection wires 210 may extend in the first direction X or in the second direction Y, or may be angled relative to the first direction X.

In some examples, as illustrated by FIG. 12 and FIG. 13, the micro light-emitting diode 120 is connected to the first signal wire VR or the second signal wire VGB through the first conductive structure 141 and the connection wires 210 of the first conductive layer 112.

In some examples, as illustrated by FIG. 12 and FIG. 13, the second micro-driver chip 152 is connected to the ground wire GND, the operating voltage wire VCC, and the data wire DATA through the second conductive structures 144 and the connection wires 210 of the first conductive layer 112, respectively. The second micro-driver chip 152 further includes three output ends, the three output ends are respectively connected to the first micro light-emitting diode, the second micro light-emitting diode, and the third micro light-emitting diode of the corresponding pixel unit.

In some examples, as illustrated by FIG. 12, the first conductive layer 112 may further include a plurality of connection blocks 211. For example, the plurality of connection blocks 211 are provided at two ends of the plurality of connection wires 210 to be connected to the plurality of signal wires 200 or the plurality of conductive structures 140. For example, the plurality of connection blocks 211 and the plurality of signal wires 200 are provide in a one-to-one correspondence and are connected through a via hole V2. For example, the plurality of connection blocks 211 and the plurality of conductive structures 140 are provided in a one-to-one correspondence. For example, an orthographic projection of the via hole V2 on the substrate 100 falls within an orthographic projection of the corresponding connection block 211 on the substrate 100. For example, an orthographic projection of the conductive structure 140 on the substrate 100 falls within the orthographic projection of the corresponding connection block 211 on the substrate 100.

In some examples, as illustrated by FIG. 13, the micro light-emitting diode substrate further includes the passivation layer 119 and the via hole V1. The passivation layer 119 is provided on the first side S1 of the substrate 100, and is provided on a side of the driver circuit layer 110 away from the substrate 100. Therefore, the driver circuit board and the flexible circuit board may be arranged on the first side S1 of the substrate 100, that is, the non-display side, an end of the flexible circuit board may be connected to the driver circuit layer 110 through the via hole V1, and another end of the flexible circuit board is connected to the driver circuit board, thereby realizing the seamless splicing between the substrates 100, reducing splicing seams at the splicing place, and improving the display effect after splicing.

An embodiment of the present disclosure further provides a display apparatus. FIG. 14 is a schematic diagram of a display apparatus provided in an embodiment of the present disclosure. As illustrated by FIG. 14, the display apparatus 300 includes any of the micro light-emitting diode substrates 200 described above. As such, the display apparatus 300 has the beneficial effect corresponding to the beneficial effect of the micro light-emitting diode substrate 200, which will not be described again here.

For example, the display apparatus described above may be an electronic product with a display function such as a TV, a computer, a navigator, a vehicle-mounted computer, an electronic picture frame, a tablet computer, a mobile phone, and the like.

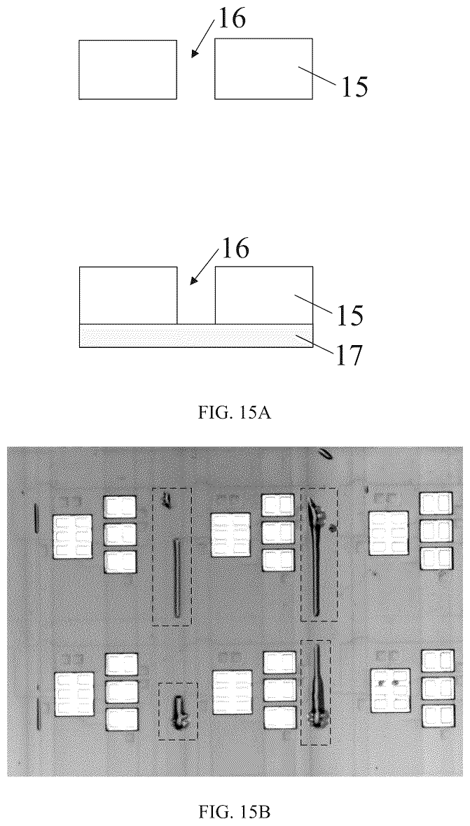

In another aspect, the mini LED and the micro LED are used for the direct display product, the driver circuit layer and the micro light-emitting diode are provided on the same side of the glass substrate, the signal wire of the driver circuit layer may be led into the back side of the glass substrate through the via hole formed by laser in the glass substrate, and the bonding region, and a combination of the driver circuit layer and the light-emitting device layer are respectively located on two sides of the glass substrate. Although this design may provide seamless splicing in all directions, as it has high requirements for the process, it has a high defect rate, problems such as film peeling, etching residue and damage to organic film are easy to occur, and the mass production is poor. FIG. 15A is a structural schematic diagram that shows a process for drilling a substrate by laser; and FIG. 15B is a structural diagram showing a micro light-emitting diode product. As illustrated by FIG. 15A, in drilling a substrate 15 by laser, when no film layer exists on a back side of the substrate 15, the laser may completely break down the substrate to form a via hole 16. However, when a film layer 17 exists on the back side of the substrate 15, it is not possible to directly use the laser to from the via hole 16 without damaging the film layer 17 on the back side. As illustrated by FIG. 15B, because the product has the film layer on the back side of the substrate, the laser drilling process can cause problems such as damages of the film layer, bulges in the film layer, and peeling of the film layer on the back side of the substrate, resulting in poor productivity, the frame selection position in the figure is the position where the damages, bulges, and peeling of the film layer occur.

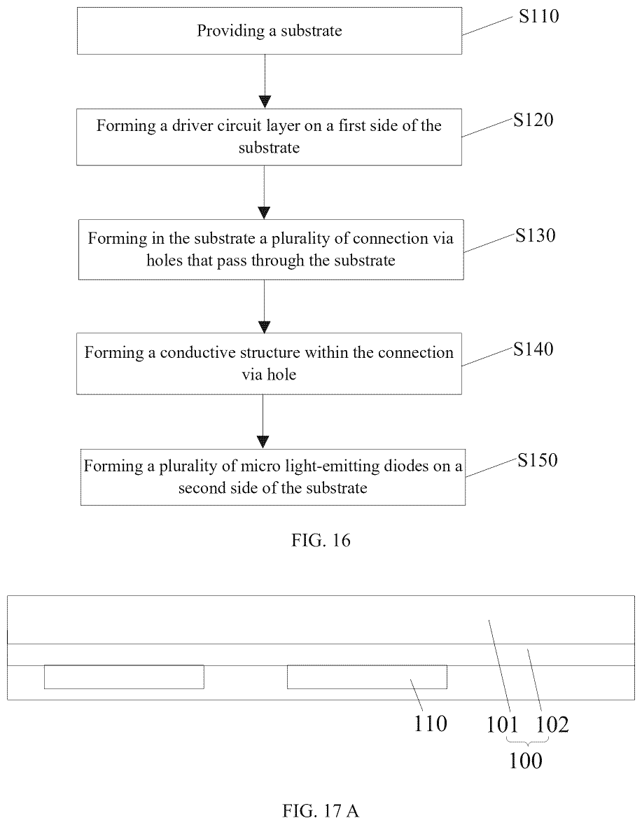

In this regard, an embodiment of the present disclosure further provides a method for manufacturing a micro light-emitting diode substrate. FIG. 16 is a flow chart of a method for manufacturing a micro light-emitting diode substrate provided in an embodiment of the present disclosure. As illustrated by FIG. 16, the method for manufacturing a micro light-emitting diode substrate includes the following steps:
S110: providing a substrate;
S120: forming a driver circuit layer on a first side of the substrate;
S130: forming in the substrate a plurality of connection via holes that pass through the substrate;
S140: forming a conductive structure within the connection via hole; and
S150: forming a plurality of micro light-emitting diodes on a second side of the substrate, the first side and the second side are opposites sides on the substrate, the plurality of connection via holes include a plurality of first connection via holes, the plurality of conductive structures include a plurality of first conductive structures, the plurality of first conductive structures are located in the plurality of first connection via holes, and the plurality of micro light-emitting diodes are electrically connected to the driver circuit layer through the plurality of first conductive structures.

In the method for manufacturing the micro light-emitting diode substrate provided in the embodiments of the present disclosure, the driver circuit layer is formed on the first side of the substrate, the micro light-emitting diode is formed on the second side of the substrate, the driver circuit layer and the micro light-emitting diode are provided on two sides of the substrate, the side on which the micro light-emitting diode is provided is a display side, and the side on which the driver circuit layer is provided is a non-display side, such that a bonding region is also located on the non-display side, thereby realizing the seamless splicing between the substrates, reducing splicing seams at the splicing place, and improving the display effect after the splicing. Compared with a conventional design where the micro light-emitting diode is fixed through a pad on a copper wire, the micro light-emitting diode is fixed on the substrate through the first conductive structure in the first connection via hole, the less copper the first conductive structure is thinned in the rework of the micro light-emitting diode, and improves the yield rate in the second die bonding process. In addition, in the rework process, the first connection via hole provides a flow leveling effect, which concentrate more copper in the first connection via hole, so that the less copper the first conductive structure is thinned in the rework process, thereby further improving the yield rate. The micro light-emitting diode on the display side is directly assembled on the display side of the substrate, and the driver circuit layer is provided on the non-display side, so that the growth of foreign matters does not affect the light-emitting or display of the micro light-emitting diode, which may improve the corrosion resistance and other performance of the product. The micro light-emitting diode and the driver circuit layer are provided on two sides of the substrate, which reduces the overall voltage and current, thereby also improving the corrosion problem of the wire. In addition, providing the micro light-emitting diode and the driver circuit layer on two sides of the substrate can result in a relatively large layout space of the micro light-emitting diode, thereby improving density of the micro light-emitting diode.

In some examples, in the method for manufacturing a micro light-emitting diode substrate, the providing the substrate includes: providing a base substrate; and forming a passivation layer on a side of the base substrate close to the driver circuit layer. That is, in this example, the substrate includes the base substrate and the passivation layer described above.

In some examples, the substrate includes, but is not limited to, a glass substrate, a printed circuit board, a resin substrate, and the like. For example, base substrate 101 includes, but is not limited to, a glass substrate, or the like.

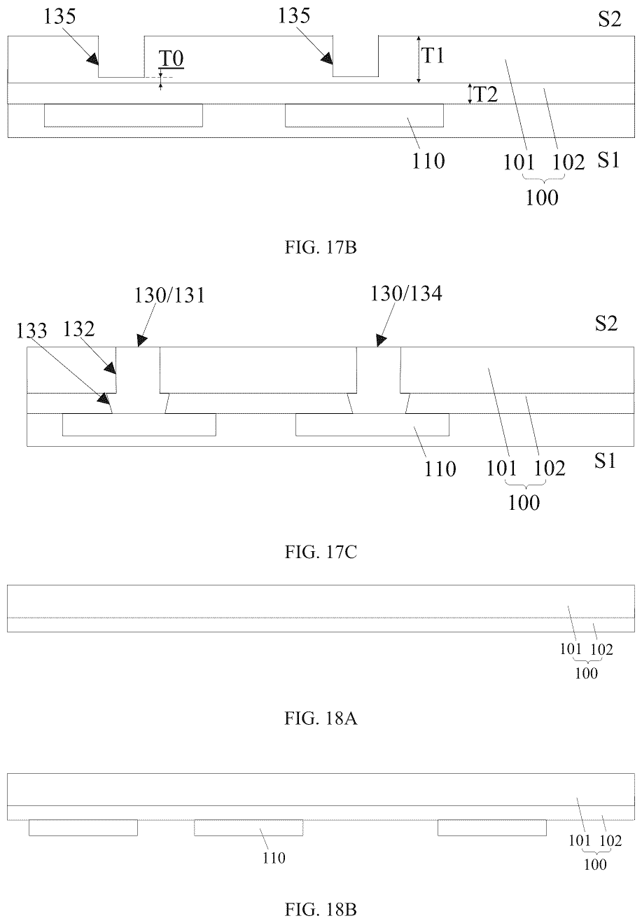

FIG. 17A to FIG. 17C are flow charts of a method for forming a connection via hole in a substrate provided in an embodiment of the present disclosure. The forming the plurality of connection via holes in the substrate includes: as illustrated by FIG. 17A and FIG. 17B, forming a blind hole 135 in the base substrate 101 by a laser process; as illustrated by FIG. 17C, etching a portion of the base substrate 101 that has not been drilled and the passivation layer 102 along an extending direction of the blind hole 135 through an etching process to form a first sub-portion 132 that passes through the base substrate 101 and a second sub-portion 133 that passes through the passivation layer 102. The first connection via hole 131 includes the first sub-portion 132 and the second sub-portion 133. In the embodiment, the blind hole 135 is formed in the base substrate 101 by the laser process, and then the portion of the base substrate 101 that has not been drilled is etched by the etching process, so that the laser process does not cause problems such as damages, bulges, and peeling of the film to the passivation layer 102.

In some examples, as illustrated by FIG. 17C, an average hole diameter of the second sub-portion 133 is greater than an average hole diameter of the first sub-portion 132. As such, the first connection via hole 131 may be shaped like a ship anchor, the first conductive structure located in the first connection via hole131 may be shaped like a ship anchor, which can improve the contact adhesive force between the first conductive structure in the first connection via hole 131 and the driver circuit layer 110, improving the performance stability.

In some examples, as illustrated by to FIG. 17C, in a direction pointing from the substrate 100 to the driver circuit layer 110, a hole diameter of the first sub-portion 132 remains substantially constant, a hole diameter of the second sub-portion 133 gradually decreases, and a maximum hole diameter of the second sub-portion 133 is larger than the hole diameter of the first sub-portion 132.

In some examples, as illustrated by FIG. 17C, a cross section of the first sub-portion 132 cut by a plane perpendicular to the substrate 100 includes a rectangle, and a cross section of the second sub-portion 133 cut by a plane perpendicular to the substrate 100 includes a trapezoid.

In some examples, as illustrated by FIG. 17B, a thickness dimension of the portion of the base substrate 101 that has not been drilled by the laser process is in a range of 0.05 mm to 0.15 mm, therefore, it can be ensured that the laser process does not penetrate the base substrate 101 when drilling the base substrate 101.

In some examples, as illustrated by FIG. 17B, a thickness of the base substrate 101 is T1, a thickness of the passivation layer 102 is T2, a depth of a hole formed by the laser process can be set to 0.85*T1, and a thickness of the remaining portion of the base substrate 101 is 0.15*T1, which is etched by the etching process, such that a thickness of a hole etched by the etching process is 0.15T1+T2.

In some examples, as illustrated by FIG. 17C, the plurality of connection via holes 130 further include a plurality of second connection via holes 134, and the micro light-emitting diode substrate further includes a plurality of micro-driver chips, which are connected to the driver circuit layer 110 through conductive structures within the plurality of second connection via holes 134. It should be noted that the second connection via hole 134 is formed through a same process as that of the first connection via hole 131, so that the second connection via hole 134 can have the same beneficial effect as the first connection via hole 131, which will not be described again herein.

In some examples, the etching process may include dry etching and wet etching. For example, it is possible to etch with a dry special gas (special gas). The dry etching special gas is not limited in the embodiments of the present disclosure.

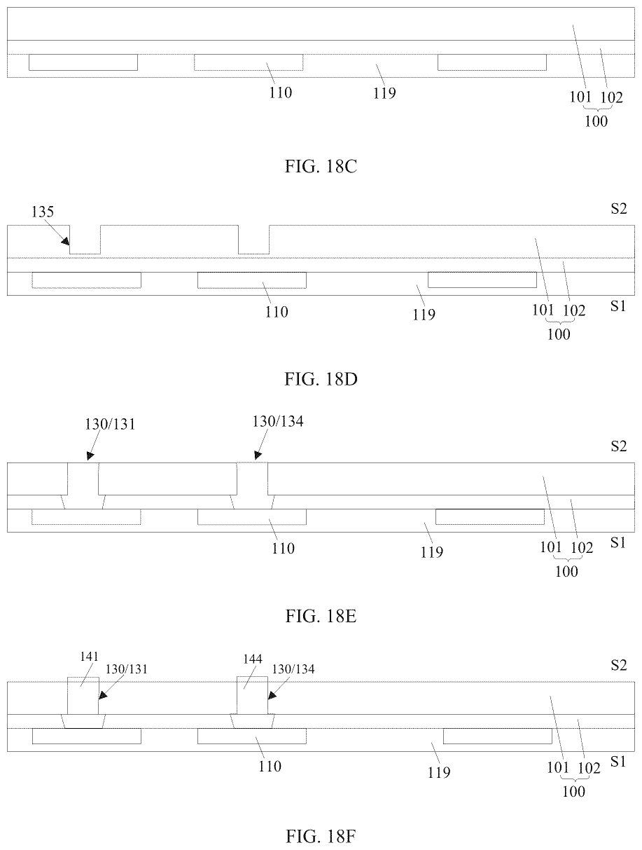

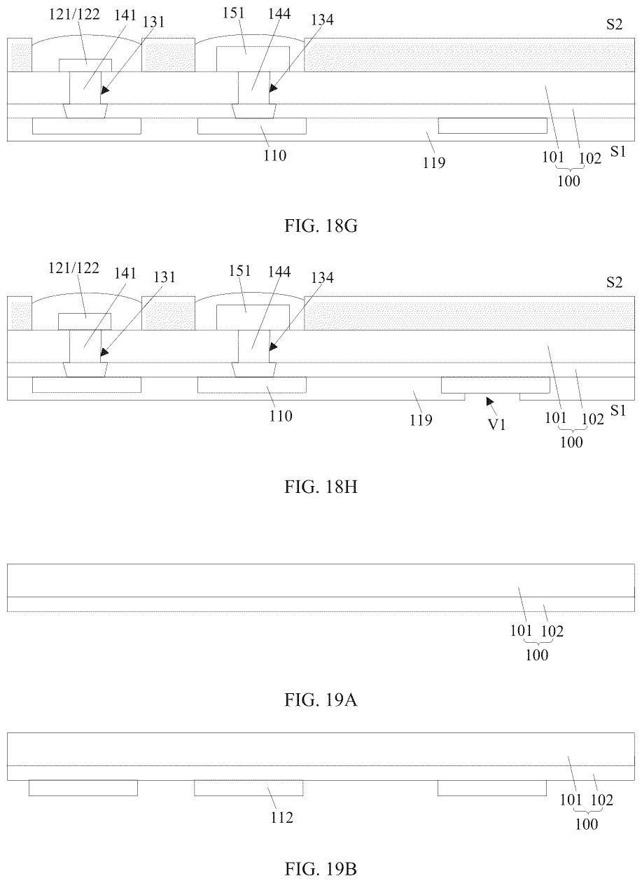

FIG. 18A to FIG. 18H are flow charts of a method for manufacturing a micro light-emitting diode substrate illustrated by FIG. 8. The method for manufacturing the micro light-emitting diode substrate includes: as illustrated by FIG. 18A, forming the first passivation layer 102 on the first side S1 of the base substrate 101, for example, the first passivation layer 102 may be a reverse stress layer, and for example, the first passivation layer 102 is made of a material that includes, but is not limited to, silicon nitride; as illustrated by FIG. 18B, forming on the first passivation layer 102 the driver circuit layer 110 through a coating process, a yellow light process, and an etching process, for example, the driver circuit layer 110 is made of a material that includes but is not limited to copper; as illustrated by FIG. 18C, depositing the passivation layer 119 on the driver circuit layer 110 by a coating apparatus, for example, the passivation layer 119 is made of a material that includes, but is not limited to, silicon nitride; as illustrated by FIG. 18D, drilling a blind hole 135 on the second side S2 of the base substrate 101 through the laser process, and stopping the laser hole drilling when the base substrate 101 still has a remaining thickness of about 0.1 mm; as illustrated by FIG. 18E, continuing to etch a portion of the base substrate 101 that has not been drilled and the first passivation layer 102 on the second side S2 of the base substrate 101 by using a dry etching special gas to finally form the first connection via hole 131 and the second connection via hole 134 illustrated by FIG. 18E; as illustrated by FIG. 18F, on the second side S2 of the base substrate 101, growing the first conductive structure 141 within the first connection via hole 131 and growing the second conductive structure 144 within the second connection via hole 134 through an electrochemical method or an immersion gold method; as illustrated by FIG. 18G, printing white oil, die bonding, reflow soldering, and dispensing glue on the second side S2 of the base substrate 101 to obtain the micro light-emitting diode 120 and the first micro-driver chip 151 that are arranged in an array on the second side S2 of the base substrate 101; as illustrated by FIG. 18H, on the first side S1 of the base substrate 101, etching the passivation layer 119 in a bonding region to form the via hole V1 to expose the driver circuit layer 110, and obtaining a final product through a bonding process. For example, the micro light-emitting diode substrate may be applied for light emitting or display. FIG. 18A to FIG. 18H only schematically show one first connection via hole 131 and one second connection via hole 134. However, this is not limited in the embodiments of the present disclosure.

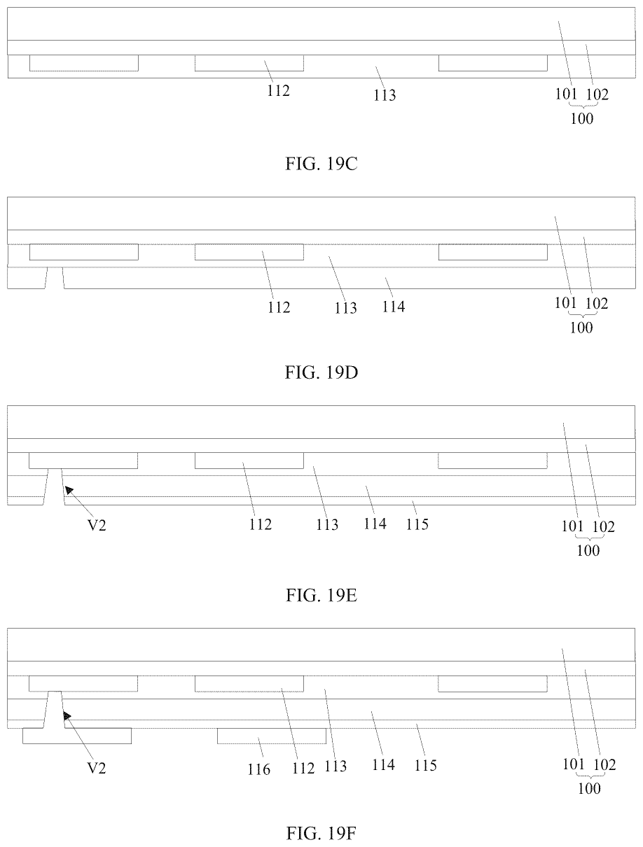

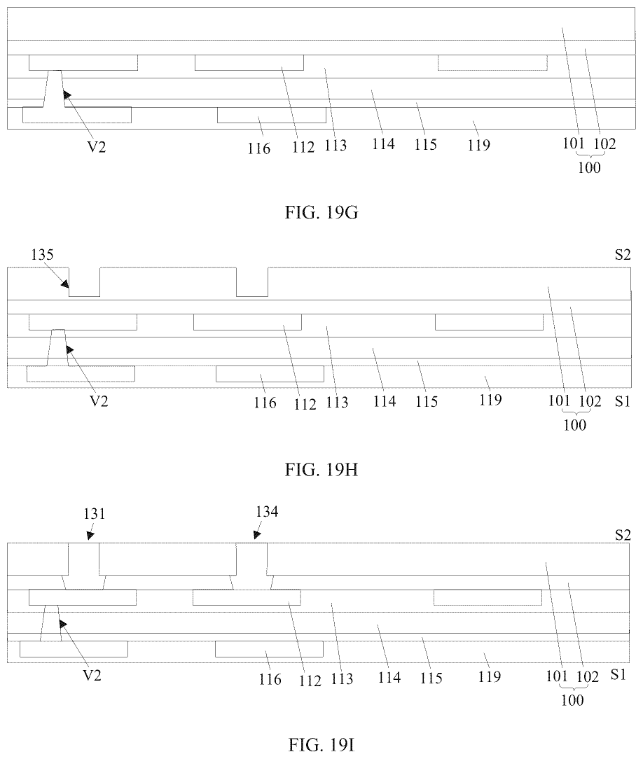

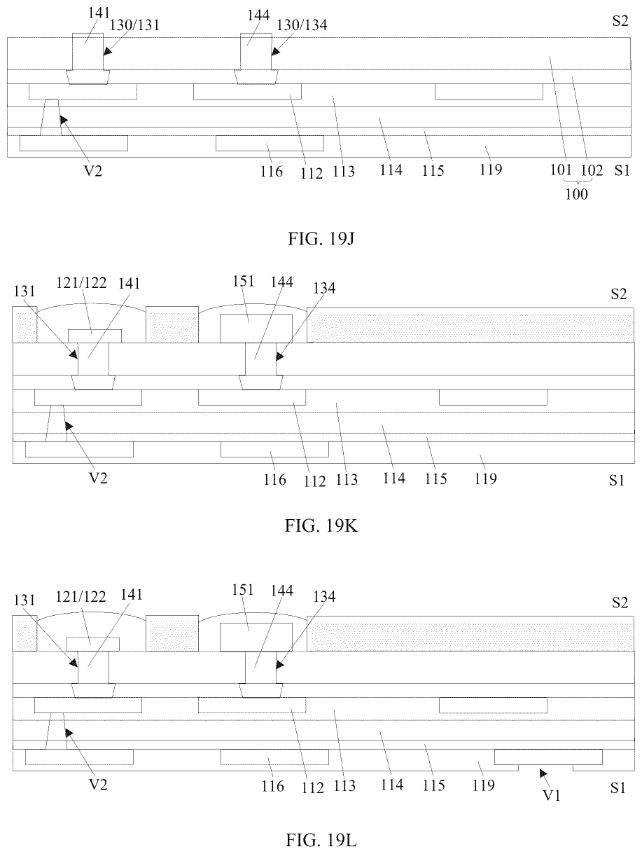

FIG. 19A to FIG. 19L are flow charts of a method for manufacturing a micro light-emitting diode substrate illustrated by FIG. 10. The method for manufacturing the micro light-emitting diode substrate includes: as illustrated by FIG. 19A, forming the first passivation layer 102 on the first side S1 of a base substrate 101, for example, the first passivation layer 102 may be a reverse stress layer, and for example, the first passivation layer 102 is made of a material that includes, but is not limited to, silicon nitride; as illustrated by FIG. 19B, forming on the first passivation layer 102 the first conductive layer 112 through a coating process, a yellow light process, and an etching process, for example, the first conductive layer 112 is made of a material that includes but is not limited to copper; as illustrated by FIG. 19C, depositing the second passivation layer 113 on the first conductive layer 112 by a coating apparatus, for example, the second passivation layer 113 is made of a material that includes, but is not limited to, silicon nitride; as illustrated by FIG. 19D, forming the patterned insulating layer 114 on the second passivation layer 113 through the yellow light process, for example, the insulating layer 114 is made of a material that includes, but is not limited to, an optical adhesive OC; as illustrated by FIG. 19E, forming the third passivation layer 115 and the via hole V2 through the coating process, the yellow light process, and the etching process; as illustrated by FIG. 19F, forming the second conductive layer 116 on the insulating layer 114 through the coating process, the yellow light process, and the etching process, for example, the second conductive layer 116 is made of a material that includes but is not limited to copper; as illustrated by FIG. 19G, depositing the passivation layer 119 on the driver circuit layer 110 through the coating apparatus, for example, the passivation layer 119 is made of a material that includes, but is not limited to, silicon nitride, and may also be a composite film, for example, the composite film layer made of silicon nitride and photoresist OC; as illustrated by FIG. 19H, drilling a blind hole 135 on the second side S2 of the base substrate 101 through the laser process, and stopping the laser hole drilling when the base substrate 101 still has a remaining thickness of about 0.1 mm; as illustrated by FIG. 19I, etching a portion of the base substrate 101 that has not been drilled and the first passivation layer 102 on the second side S2 of the base substrate 101 by using a dry etching special gas to finally form the first connection via hole 131 and the second connection via hole 134 illustrated by FIG. 19I; as illustrated by FIG. 19J, on the second side S2 of the base substrate 101, growing the first conductive structure 141 within the first connection via hole 131 and growing the second conductive structure 144 within the second connection via hole 134 through an electrochemical method or an immersion gold method; as illustrated by FIG. 19K, printing white oil, die bonding, reflow soldering, and dispensing glue on the second side S2 of the base substrate 101 to obtain the micro light-emitting diode 120 and the first micro-driver chip 151 that are arranged in an array on the second side S2 of the base substrate 101. As illustrated by FIG. 19L, on the first side S1 of the base substrate 101, a bonding region is etched to form the via hole V1 to expose the driver circuit layer 110, and a final product is obtained through a bonding process. For example, the micro light-emitting diode substrate may be applied for light emitting or display. FIG. 19A to FIG. 19L only schematically show one first connection via hole 131 and one second connection via hole 134. However, this is not limited in the embodiments of the present disclosure.

For example: the manufacturing method illustrated by FIG. 19A to FIG. 19L may also be applied in the micro light-emitting diode substrate illustrated by FIG. 12, so this is not described again here.

The following points required to be explained:

(1) the drawings of the embodiments of the present disclosure only relate to the structures related to the embodiments of the present disclosure, and other structures can refer to the general design.

(2) without conflict, the embodiments of the present disclosure and the features in the embodiments may be combined with each other.

The above is only the specific embodiment of this disclosure, but the protection scope of the present disclosure is not limited thereto. Any person familiar with the technical field can easily think of changes or substitutions within the technical scope disclosed in the present disclosure, and they should be included in the protection scope of the present disclosure. Therefore, the scope of protection of the present disclosure should be based on the scope of protection of the claims.

1. A micro light-emitting diode substrate, comprising:
a substrate;
a driver circuit layer, provided on a first side of the substrate;
a plurality of micro light-emitting diodes, provided on a second side of the substrate, wherein the second side and the first side are two opposite sides of the substrate;
a plurality of connection via holes, passing through the substrate; and
a plurality of conductive structures, located in the plurality of connection via holes and arranged in a one-to-one correspondence to the plurality of connection via holes,
wherein the plurality of connection via holes comprise a plurality of first connection via holes, the plurality of conductive structures comprise a plurality of first conductive structures, the plurality of first conductive structures are located in the plurality of first connection via holes, and the plurality of micro light-emitting diodes are electrically connected to the driver circuit layer through the plurality of first conductive structures.

2. The micro light-emitting diode substrate according to claim 1, wherein each of the plurality of micro light-emitting diodes comprises a first electrode and a second electrode, an end of each of the plurality of first conductive structures is connected to the driver circuit layer, and another end of each of the plurality of first conductive structures is exposed as a pad on the second side of the substrate, and the pad is configured to be connected to the first electrode or the second electrode.

3. The micro light-emitting diode substrate according to claim 1, wherein at least one of the plurality of first connection via holes comprises:
a first sub-portion; and
a second sub-portion, provided on a side of the first sub-portion close to the driver circuit layer,
wherein an average hole diameter of the second sub-portion is larger than an average hole diameter of the first sub-portion.

4. The micro light-emitting diode substrate according to claim 3, wherein in a direction pointing from the substrate to the driver circuit layer, a hole diameter of the first sub-portion remains constant, a hole diameter of the second sub-portion gradually decreases, and a maximum hole diameter of the second sub-portion is larger than the hole diameter of the first sub-portion.

5. The micro light-emitting diode substrate according to claim 4, wherein a cross section of the first sub-portion cut by a plane perpendicular to the substrate comprises a rectangle, and a cross section of the second sub-portion cut by a plane perpendicular to the substrate comprises a trapezoid.

6. The micro light-emitting diode substrate according to claim 3, wherein the substrate comprises a base substrate and a first passivation layer, the first sub-portion is located in the base substrate, and the second sub-portion is located in the first passivation layer.

7. The micro light-emitting diode substrate according to claim 1, wherein at least one of the plurality of first conductive structures comprises:
a first conductive portion;
a second conductive portion, provided on a side of the first conductive portion close to the driver circuit layer,
wherein an average radial dimension of the second conductive portion is greater than an average radial dimension of the first conductive portion.

8. The micro light-emitting diode substrate according to claim 7, wherein in a direction pointing from the substrate to the driver circuit layer, a radial dimension of the first conductive portion remains constant, a radial dimension of the second conductive portion gradually decreases, and a maximum radial dimension of the second conductive portion is larger than the radial dimension of the first conductive portion.

9-10. (canceled)

11. The micro light-emitting diode substrate according to claim 1, wherein the driver circuit layer comprises a plurality of signal wires and a plurality of connection wires, and each of the plurality of micro light-emitting diodes is connected to a signal wire of the plurality of signal wires through a first conductive structure of the plurality of first conductive structures and a connection wire of the plurality of connection wires.

12. The micro light-emitting diode substrate according to claim 11, further comprising:
a plurality of light-emitting units, each of the plurality of light-emitting units comprising multiple micro light-emitting diodes of the plurality of micro light-emitting diodes; and
a plurality of first micro-driver chips, provided in a correspondence to the plurality of light-emitting units, wherein each of the plurality of first micro-driver chips is configured to drive a corresponding light-emitting unit of the plurality of light-emitting units to emit light,
wherein the plurality of connection via holes further comprise a plurality of second connection via holes, the plurality of conductive structures further comprise a plurality of second conductive structures, the plurality of second conductive structures are located in the plurality of second connection via holes, and the plurality of first micro-driver chips are connected to the driver circuit layer through the plurality of second conductive structures,
the plurality of signal wires comprise a driving voltage wire, a ground wire, an operating voltage wire and a source address wire, each of the plurality of micro light-emitting diodes is connected to the driving voltage wire through a first conductive structure of the plurality of first conductive structures and a connection wire of the plurality of connection wires, each of the plurality of first micro-driver chips is connected to the ground wire, the operating voltage wire, and the source address wire respectively through a second conductive structure of the plurality of second conductive structures and a connection wire of the plurality of connection wires, alternatively, each of the plurality of first micro-driver chips is connected to the ground wire, the operating voltage wire and the source address wire through each of the plurality of second conductive structures respectively,
each of the plurality of first micro-driver chips comprises an output end, and each of the plurality of micro light-emitting diodes is connected to the output end through a first conductive structure of the plurality of first conductive structures and a connection wire of the plurality of connection wires.

13. The micro light-emitting diode substrate according to claim 1, wherein the driver circuit layer comprises:
a first conductive layer;
a second passivation layer, provided on a side of the first conductive layer away from the substrate;
an insulating layer, provided on a side of the second passivation layer away from the first conductive layer;
a third passivation layer, provided on a side of the insulating layer away from the second passivation layer;
a second conductive layer, provided on a side of the third passivation layer away from the insulation layer; and
a plurality of first via holes, passing through the second passivation layer, the insulating layer, and the third passivation layer,
wherein the first conductive layer comprises a plurality of connection wires, the second conductive layer comprises a plurality of signal wires, the plurality of micro light-emitting diodes are connected to the plurality of connection wires of the first conductive layer through the plurality of first conductive structures, and the plurality of connection wires of the first conductive layer are connected to the plurality of signal wires of the second conductive layer through the plurality of first via holes.

14. The micro light-emitting diode substrate according to claim 13, further comprising:
a plurality of light-emitting units, each of the plurality of light-emitting units comprising multiple micro light-emitting diodes of the plurality of micro light-emitting diodes; and
a plurality of first micro-driver chips, provided in a correspondence to the plurality of light-emitting units, wherein each of the plurality of micro-driver chips is configured to drive a corresponding light-emitting unit of the plurality of light-emitting units to emit light,
wherein the plurality of connection via holes further comprise a plurality of second connection via holes, the plurality of conductive structures further comprise a plurality of second conductive structures, the plurality of second conductive structures are located in the plurality of second connection via holes, and the plurality of first micro-driver chips are connected to the driver circuit layer through each of the plurality of second conductive structures,
the plurality of signal wires comprise a driving voltage wire, a ground wire, an operating voltage wire, and a source address wire, each of the plurality of micro light-emitting diodes is connected to the driving voltage wire through a first conductive structure of the plurality of first conductive structures and a connection wire of the plurality of connection wires of the first conductive layer, each of the plurality of first micro-driver chips is connected to the ground wire, the operating voltage wire, and the source address wire respectively through a second conductive structure of the plurality of second conductive structures and a connection wire of the plurality of connection wires of the first conductive layer,
each of the plurality of first micro-driver chips comprises an output end, and each of the plurality of micro light-emitting diodes is connected to the output end through a connection wire of the plurality of connection wires.

15. The micro light-emitting diode substrate according to claim 13, further comprising:
a plurality of pixel units; and
a plurality of second micro-driver chips, provided in a correspondence to the plurality of pixel units, wherein each of the plurality of second micro-driver chips is configured to drive a corresponding pixel unit of the plurality of pixel units for display,
wherein the plurality of micro light-emitting diodes comprise a first micro light-emitting diode, a second micro light-emitting diode, and a third micro light-emitting diode, the first micro light-emitting diode is configured to emit light of a first color, the second micro light-emitting diode is configured to emit light of a second color, and the third micro light-emitting diode is configured to emit light of a third color, and each of the plurality of pixel units comprises the first micro light-emitting diode, the second micro light-emitting diode, and the third micro light-emitting diode,
the plurality of connection via holes further comprise a plurality of second connection via holes, the plurality of conductive structures further comprise a plurality of second conductive structures, the plurality of second conductive structures are located in the plurality of second connection via holes, and the plurality of second micro-driver chips are connected to the driver circuit layer through the plurality of second conductive structures.

16-17. (canceled)

18. A display apparatus, comprising the micro light-emitting diode substrate according to claim 1.

19. A manufacturing method of a micro light-emitting diode substrate, comprising:
providing a substrate;
forming a driver circuit layer on a first side of the substrate;
forming in the substrate a plurality of connection via holes that pass through the substrate;
forming a conductive structure within each of the plurality of connection via holes; and
forming a plurality of micro light-emitting diodes on a second side of the substrate,
wherein the first side and the second side are two opposite sides of the substrate, the plurality of connection via holes comprise a plurality of first connection via holes, the plurality of conductive structures comprise a plurality of first conductive structures, the plurality of first conductive structures are located in the plurality of first connection via holes, and the plurality of micro light-emitting diodes are electrically connected to the driver circuit layer through the plurality of first conductive structures.

20. The manufacturing method according to claim 19, wherein the providing the substrate comprises:
providing a base substrate; and
forming a passivation layer on a side of the base substrate close to the driver circuit layer.

21. The manufacturing method according to claim 20, wherein the forming in the substrate the plurality of connection via holes comprises:
forming a blind hole in the base substrate by using a laser process; and
etching a portion of the base substrate that has not been drilled and the passivation layer along an extending direction of the blind hole through an etching process to form a first sub-portion that passes through the base substrate and a second sub-portion that passes through the passivation layer,
wherein each of the plurality of first connection via holes comprises the first sub-portion and the second sub-portion.

22. The manufacturing method according to claim 21, wherein an average hole diameter of the second sub-portion is larger than an average hole diameter of the first sub-portion.

23. The manufacturing method according to claim 22, wherein in a direction pointing from the substrate to the driver circuit layer, a hole diameter of the first sub-portion remains constant, a hole diameter of the second sub-portion gradually decreases, and a maximum hole diameter the second sub-portion is larger than the hole diameter of the first sub-portion.

24. (canceled)

25. The manufacturing method according to claim 21, wherein a thickness diameter of the portion of the base substrate that has not been drilled is in a range of 0.05 mm to 0.15 mm.
